(19) United States
(12) Patent Application Publication
(10) Pub. No.: US 2023/0328982 A1
(43) Pub. Date: Oct. 12, 2023

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Ting-Feng LIAO, Hsin-chu (TW); Mao-Yuan WENG, Hualien City, Hualien County (TW); Kuang-Wen LIU, Hsin-chu (TW)

(21) Appl. No.: 17/717,196

(22) Filed: Apr. 11, 2022

(51) Int. Cl. H01L 27/11582; H01L 21/768

(52) U.S. Cl. CPC H01L 27/11582; H01L 21/76877; H01L 21/76843

(57) ABSTRACT

A semiconductor structure is provided. The semiconductor structure includes a substrate, a stack, active structures connecting structures and isolation layers. The stack is disposed on the substrate. The active structures penetrate through the stack in sub-array regions thereof. A plurality of memory cells are defined by cross points of gate electrodes in the stack and the active structures. The connecting structures penetrate through the stack between the sub-array regions. Each connecting structure includes a first portion, a second portion and a third portion. The first portion is formed as an outermost layer of the connecting structure and formed of polysilicon. The second portion is disposed in a space defined by the first portion and formed of amorphous silicon. The third portion is disposed on the second portion and formed of amorphous silicon. The isolation layers are disposed between sidewalls of the stack and the connecting structures.

### TECHNICAL FIELD

This disclosure relates to a semiconductor structure and a method for manufacturing the same. More particularly, this disclosure relates to a semiconductor structure comprising a 3D memory array and a method for manufacturing the same.

### BACKGROUND

Stereoscopic configurations have been developed for increasing the density of the memories. In some of the configurations, a stack and vertical structures penetrating through the stack are provided, and memory cells are defined by cross points of layers in the stack and the vertical structures, so as to build a 3D memory array. Stress produced in the manufacturing processes may cause bending of previously-formed structures. The bending of vertical structures may lead to mis landing of vias thereon, and thereby may result in short and leakage.

### SUMMARY

The disclosure is directed to a solution of the problem as described above.

According to some embodiments, a semiconductor structure is provided. The semiconductor structure comprises a substrate, a stack, a plurality of active structures, a plurality of connecting structures and a plurality of isolation layers. The stack is disposed on the substrate. The stack has a plurality of sub-array regions. The stack comprises a plurality of gate electrodes and a plurality of dielectric layers disposed alternately. The active structures penetrate through the stack in the sub-array regions. A plurality of memory cells are defined by cross points of the gate electrodes and the active structures. The connecting structures penetrate through the stack between the sub-array regions. Each of the connecting structures comprises a first portion, a second portion and a third portion. The first portion is formed as an outermost layer of the connecting structure. The first portion is formed of polysilicon. The second portion is disposed in a space defined by the first portion. The second portion is formed of amorphous silicon. The third portion is disposed on the second portion. The third portion is formed of amorphous silicon. The isolation layers are disposed between sidewalls of the stack and the connecting structures.

According to some embodiments, a method for manufacturing a semiconductor structure is provided. The method comprises the following steps. First, a partially formed structure is provided. The partially formed structure comprising a substrate, a stack and a plurality of active structures. The stack is formed on the substrate. The stack has a plurality of sub-array regions and a plurality of openings penetrating through the stack between the sub-array regions. The stack comprises a plurality of gate electrodes and a plurality of dielectric layers disposed alternately. The active structures penetrate through the stack in the sub-array regions. Then, a plurality of isolation layers are formed in the openings along sidewalls of the stack. Thereafter, a plurality of connecting structures are formed in remaining spaces of the openings. In this step, first portions of polysilicon are formed along the isolation layers, second portions of amorphous silicon are formed in spaces defined by the first portions, and third portions of amorphous silicon are formed on the second portion.

### BRIEF DESCRIPTION OF THE DRAWINGS

FIG. 1 illustrates an exemplary semiconductor structure according to embodiments.

FIGS. 2A-2Q illustrate various stages of an exemplary method for manufacturing a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The following description and the accompanying drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

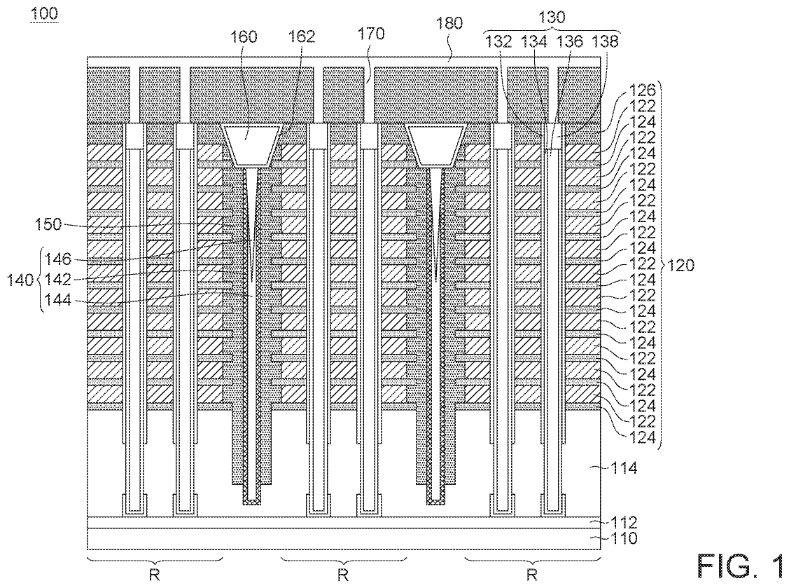

Referring to FIG. 1, an exemplary semiconductor structure 100 according to embodiments is shown. The semiconductor structure 100 comprises a substrate 110, a stack 120, a plurality of active structures 130, a plurality of connecting structures 140 and a plurality of isolation layers 150. The stack 120 is disposed on the substrate 110. The stack 120 has a plurality of sub-array regions R. The stack 120 comprises a plurality of gate electrodes 122 and a plurality of dielectric layers 124 disposed alternately. The active structures 130 penetrate through the stack 120 in the sub-array regions R. A plurality of memory cells (not shown) are defined by cross points of the gate electrodes 122 and the active structures 130. The connecting structures 140 penetrate through the stack 120 between the sub-array regions R. Each of the connecting structures 140 comprises a first portion 142, a second portion 144 and a third portion 146. The first portion 142 is formed as an outermost layer of the connecting structure 140. The first portion 142 is formed of polysilicon. The second portion 144 is disposed in a space defined by the first portion 142. The second portion 144 is formed of amorphous silicon. The third portion 146 is disposed on the second portion 144. The third portion 146 is formed of amorphous silicon. The isolation layers 150 are disposed between sidewalls of the stack 120 and the connecting structures 140.

Specifically, the substrate 110 may be a substrate typically used in the semiconductor field without particular limitation. In some embodiments, the semiconductor structure 100 further comprises an electronic device layer 112 disposed on the substrate 110. The electronic device layer 112 comprises electronic devices, such as MOS devices and the like. Additionally or alternatively, portions of said electronic devices may be formed in the substrate 110. According to some embodiments, the semiconductor structure 100 may further comprise a bottom conductive layer 114 disposed on the electronic device layer 112. The bottom conductive layer 114 may comprise polysilicon, but the disclosure is not limited thereto. In conditions that the electronic device layer 112 and the bottom conductive layer 114 are included, the stack 120 may be disposed on the bottom conductive layer 114. The active structures 130 may penetrate through the stack 120 and the bottom conductive layer 114 and land on the electronic device layer 112. The connecting structures 140 may stop in the bottom conductive layer 114 and electrically connect with the bottom conductive layer 114.

As to the stack 120, the gate electrodes 122 may be metal gate electrodes and comprise tungsten (W). Other typical structures in metal gate electrodes, such as a high-k layer and the like, may also be included in the gate electrodes 122. The dielectric layers 124 may comprise oxide, but the disclosure is not limited thereto. In some embodiments, the stack 120 further comprises a hard mask layer 126 disposed on the gate electrodes 122 and the dielectric layers 124. The hard mask layer 126 may comprise oxide, but the disclosure is not limited thereto.

According to some embodiments, each of the active structures 130 may comprise a memory layer 132, a channel layer 134, a dielectric material 136 and a contact 138. The memory layer 132 is formed as an outermost layer of the active structure 130. The memory layer 132 may comprise an ONO layer or the like, but the disclosure is not limited thereto. The channel layer 134 is disposed along the memory layer 132. The channel layer 134 may comprise polysilicon, but the disclosure is not limited thereto. The dielectric material 136 is disposed in a space defined by the channel layer 134. The dielectric material 136 may comprise silicon nitride, but the disclosure is not limited thereto. The contact 138 is disposed on the dielectric material 136. In some embodiments, the memory layers 132 have disconnections in the bottom conductive layer 114 such that the channel layers 134 are connected by the bottom conductive layer 114.

In the connecting structures 140, a combined structure of the second portion 144 and the third portion 146 are surrounded by the first portion 142. As such, each of the connecting structures 140 has only a thin liner portion (i.e., the first portion 142) is formed of polysilicon, and a thicker portion (i.e., the combined structure of the second portion 144 and the third portion 146) is formed of amorphous silicon. Such a structure is beneficial for reducing stress to other components in the semiconductor structure 100 since non-crystalline silicon results in less thermal stress than crystalline silicon. In some embodiments, the first portion 142 may comprise a side part disposed along sidewalls of the stack 120 and a bottom part connecting the side part. In some embodiments, an interface between the second portion 144 and the third portion 146 can be observed, and the interface is concave for the second portion 144.

The isolation layers 150 are disposed between the sidewalls of the stack 120 and the connecting structures 140 to isolate the conductive first portion 142 from the gate electrodes 122 in the stack 120. The isolation layers 150 may comprise oxide, but the disclosure is not limited thereto.

The semiconductor structure 100 may further comprise a plurality of plugs 160 and a plurality of barrier layers 162. The plugs 160 are disposed on the connecting structures 140. The plugs 160 may comprise tungsten, but the disclosure is not limited thereto. The barrier layers 162 wrap the plugs 160, respectively. In some embodiments, the plugs 160 have substantially flat bottom surfaces. The semiconductor structure 100 may further comprise a plurality of vias 170 landing on the active structures 130.

According to some embodiments, the bottom conductive layer 114 may be functioned as a common source line, the connecting structures 140 may be functioned as common source line connecting structures, the gate electrodes 122 in the stack 120 may be further functioned as a string select line, word lines and a ground select line, and the semiconductor structure 100 may further comprise a plurality of bit lines 180 disposed over the stack 120 and connected to the active structures 130 through the vias 170.

Now the disclosure is directed to a method for manufacturing a semiconductor structure. The method comprises the following steps. First, a partially formed structure is provided. The partially formed structure comprising a substrate, a stack and a plurality of active structures. The stack is formed on the substrate. The stack has a plurality of sub-array regions and a plurality of openings penetrating through the stack between the sub-array regions. The stack comprises a plurality of gate electrodes and a plurality of dielectric layers disposed alternately. The active structures penetrate through the stack in the sub-array regions. Then, a plurality of isolation layers are formed in the openings along sidewalls of the stack. Thereafter, a plurality of connecting structures are formed in remaining spaces of the openings. In this step, first portions of polysilicon are formed along the isolation layers, second portions of amorphous silicon are formed in spaces defined by the first portions, and third portions of amorphous silicon are formed on the second portion.

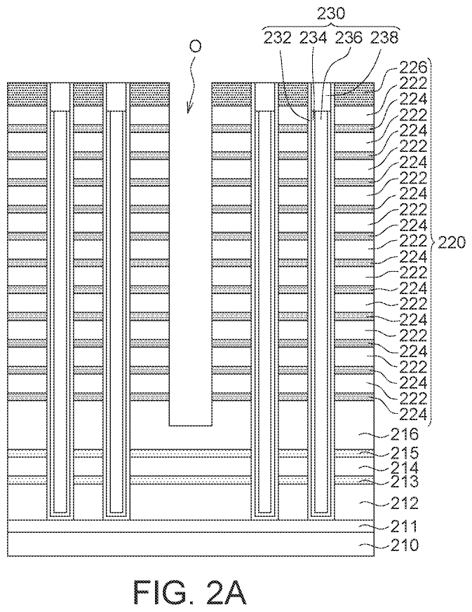

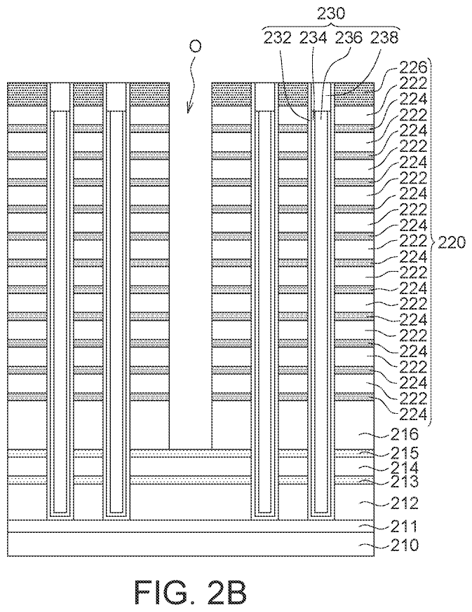

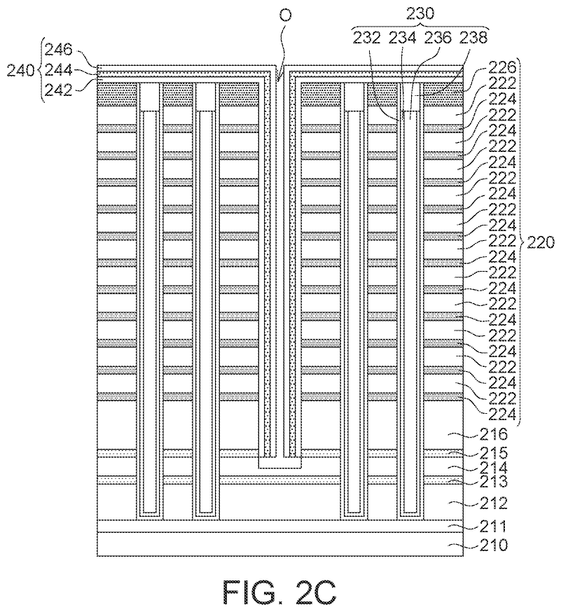

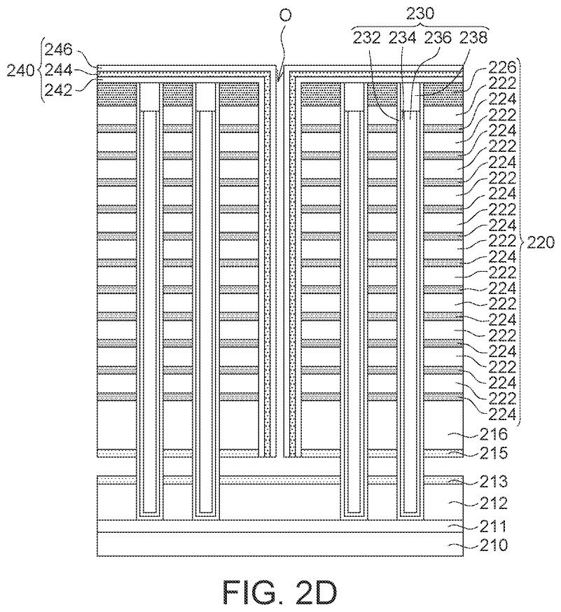

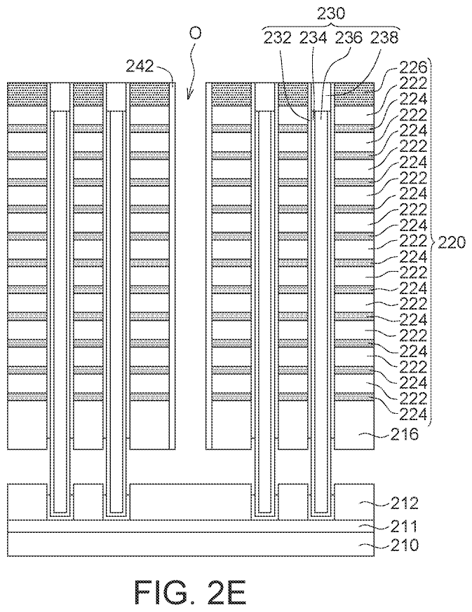

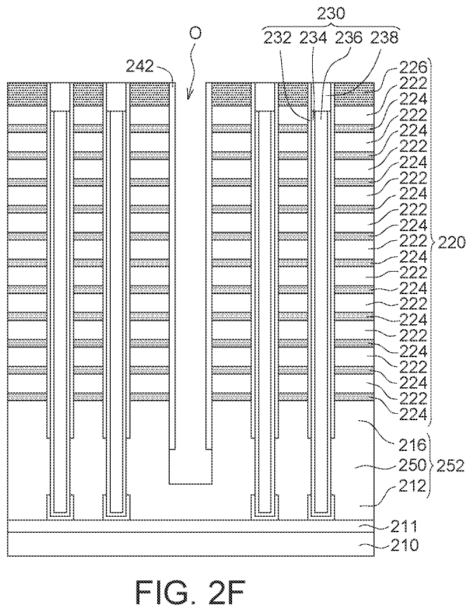

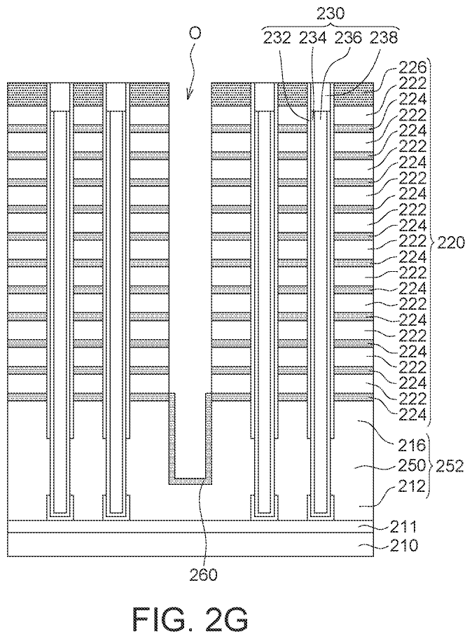

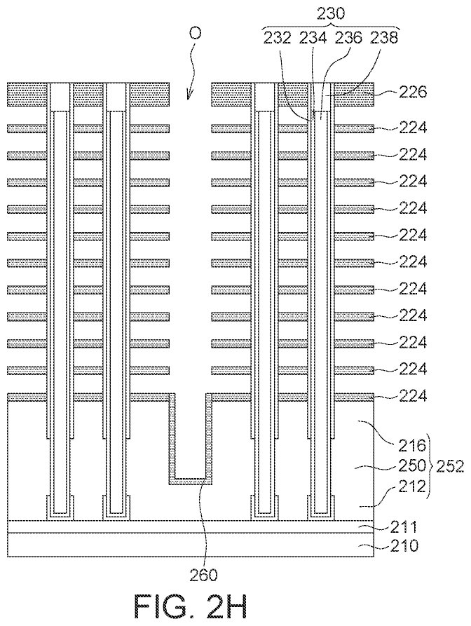

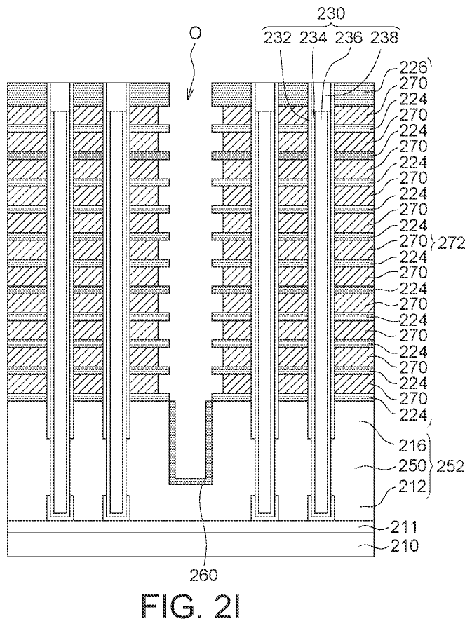

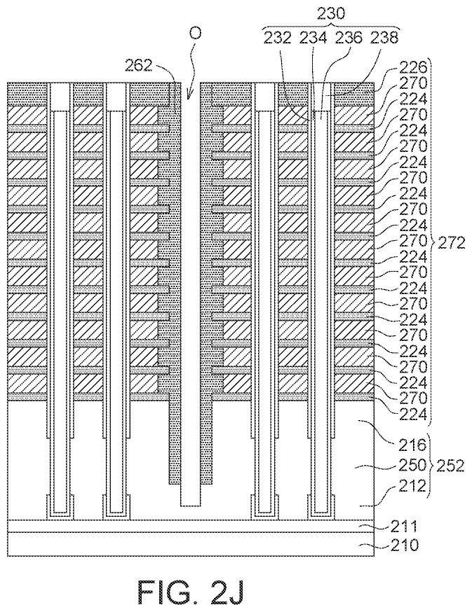

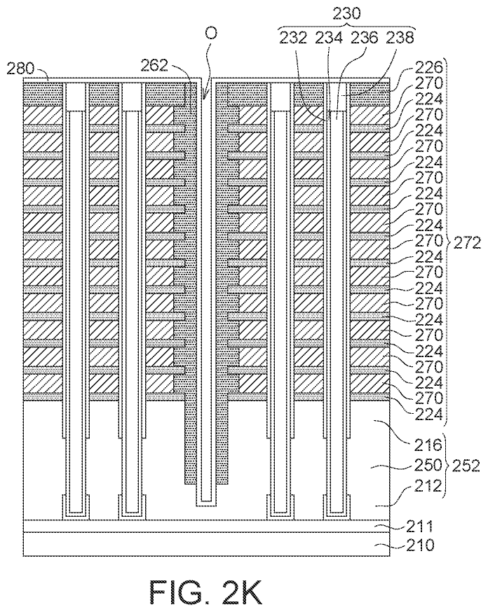

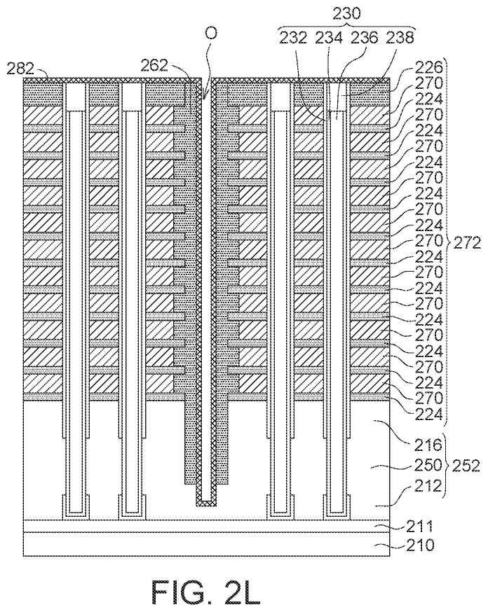

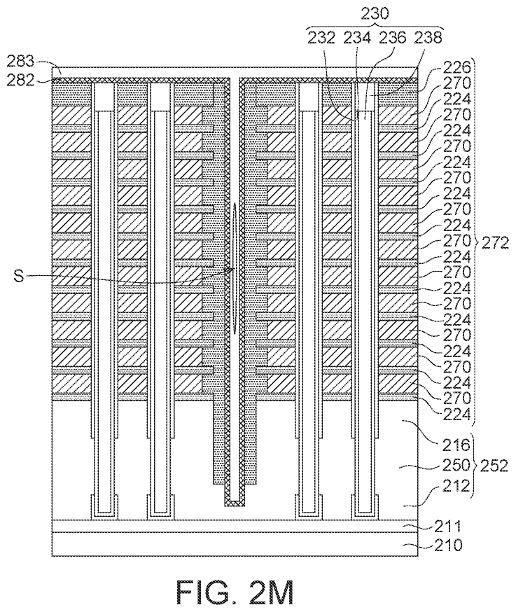

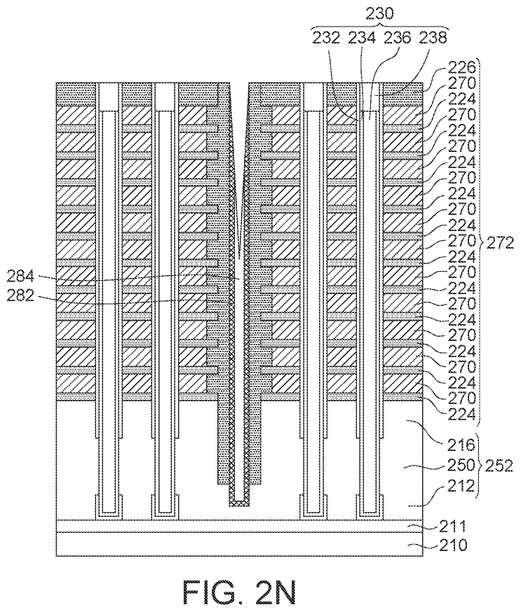

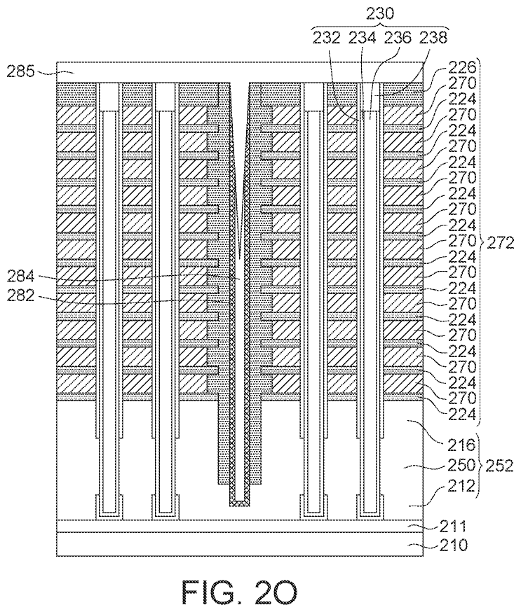

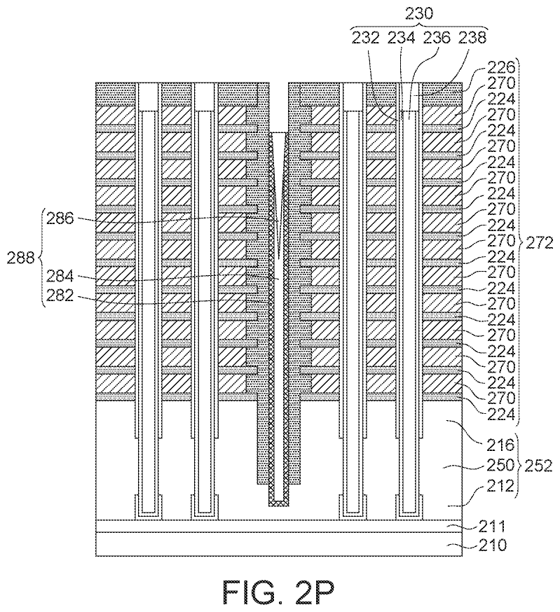

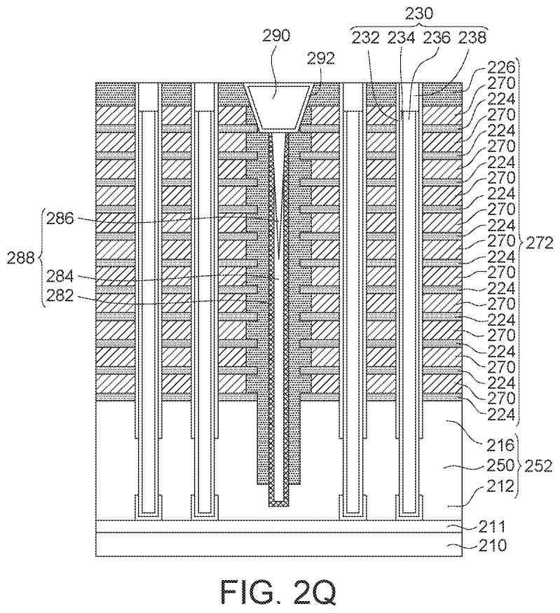

Referring to FIGS. 2A-2Q, various stages of an exemplary method for manufacturing a semiconductor structure according to embodiments are shown.

As shown in FIG. 2A, a substrate 210 may be provided. An initial stack 220 may be formed on the substrate 210. The initial stack 220 comprises a plurality of sacrificial layers 222 and a plurality of dielectric layers 224 formed alternately. In some embodiments, the initial stack 220 may further comprise a hard mask layer 226 on the sacrificial layers 222 and the dielectric layers 224. The hard mask layer 226 may be formed of oxide, but the disclosure is not limited thereto. Active structures 230 may be formed penetrating through the initial stack 220 in sub-array regions (R shown in FIG. 1). Each of the active structures 230 comprises a memory layer 232, a channel layer 234, a dielectric material 236 and a contact 238. The memory layer 232 is formed along a sidewall of the initial stack 220. The memory layer 232 may be formed of an ONO layer or the like, but the disclosure is not limited thereto. The channel layer 234 is form along the memory layer 232. The channel layer 234 may be formed of polysilicon, but the disclosure is not limited thereto. The dielectric material 236 is form in a space defined by the channel layer 234. The dielectric material 236 may be formed of silicon nitride, but the disclosure is not limited thereto. The contact 238 is form on the dielectric material 236. Openings O are formed penetrating through the initial stack 220 between the sub-array regions. The openings O may be formed as slits.

According to some embodiments, before forming the initial stack 220, an electronic device layer 211 may be formed on the substrate 210. The electronic device layer 211 comprises electronic devices, such as MOS devices and the like. A bottom stop layer 212 may be formed on the electronic device layer 211. The bottom stop layer 212 may be formed of n+ polysilicon, but the disclosure is not limited thereto. A first bottom dielectric layer 213 may be formed on the bottom stop layer 212. The first bottom dielectric layer 213 may be formed of oxide, but the disclosure is not limited thereto. A bottom sacrificial layer 214 may be formed on the first bottom dielectric layer 213. The bottom sacrificial layer 214 may be formed of polysilicon, but the disclosure is not limited thereto. A second bottom dielectric layer 215 may be formed on the bottom sacrificial layer 214. The second bottom dielectric layer 215 may be formed of oxide, but the disclosure is not limited thereto. An etch stop layer 216 may be formed on the second bottom dielectric layer 215. The etch stop layer 216 may be formed of polysilicon, but the disclosure is not limited thereto. In such cases, the initial stack 220 may be formed on the etch stop layer 216, the active structures 230 may further penetrate through the etch stop layer 216, the second bottom dielectric layer 215, the bottom sacrificial layer 214, the first bottom dielectric layer 213 and the bottom stop layer 212 and land on the electronic device layer 211, and the openings O may further penetrate into the etch stop layer 216 and the second bottom dielectric layer 215 and stop in the bottom sacrificial layer 214.

As shown in FIG. 2B, the etch stop layer 216 is etched through the openings O. As such, the openings O further penetrate through the etch stop layer 216 and stop on the second bottom dielectric layer 215.

Then, a spacer 240 may be formed on the initial stack 220 and into the openings O in a conformal manner. The spacer 240 may comprise a nitride layer 242, an oxide layer 244 and a nitride layer 246 in sequence. As shown in FIG. 2C, an etching process is conducted, and bottom parts of the spacer 240 and portions of the bottom sacrificial layer 214 corresponding to the openings O are removed. At this time, the openings O penetrate through the initial stack 220, the etch stop layer 216 and the second bottom dielectric layer 215 and stop in the bottom sacrificial layer 214. Then, as shown in FIG. 2D, the bottom sacrificial layer 214 are removed through the openings O.

As shown in FIG. 2E, portions of the memory layers 232 located at positions corresponding to the bottom sacrificial layer 214 are removed through the openings O. The nitride layer 246 may also be removed. In addition, the first bottom dielectric layer 213 and the second bottom dielectric layer 215 are removed through the openings O. The oxide layer 244 may also be removed.

As shown in FIG. 2F, a conductive material 250 is filled into a space formed by removing the bottom sacrificial layer 214, the portions of the memory layers 232, the first bottom dielectric layer 213 and the second bottom dielectric layer 215. The conductive material 250 may be polysilicon, but the disclosure is not limited thereto. In some embodiments, the bottom stop layer 212 and the etch stop layer 216 are conductive, and the conductive material 250 filled into the space formed by removing the bottom sacrificial layer, 214, the portions of the memory layers 232, the first bottom dielectric layer 213 and the second bottom dielectric layer 215 together with the bottom stop layer 212 and the etch stop layer 216 constitutes a bottom conductive layer 252.

As shown in FIG. 2G, the nitride layer 242 is removed, such as by a dip etching process. An oxide layer 260 is formed on sidewalls of the bottom conductive layer 252 exposed by the openings O, such as by an oxidation process for to the sidewalls of the bottom conductive layer 252.

As shown in FIG. 2H, sacrificial layers 222 are removed. Then, as shown in FIG. 2I, gate electrodes 270 are formed in spaces formed by removing the sacrificial layers 222. The gate electrodes 270 may comprise tungsten, and optionally comprise high-k layers and the like. A chemical vapor deposition (CVD) process and an etching process may be used, but the disclosure is not limited thereto. The sacrificial layers 222 of the initial stack 220 are replaced with the gate electrodes 270 to form the stack 272.

As such, said partially formed structure can be provided. The partially formed structure comprises a substrate 210, a stack 272 and a plurality of active structures 230. The stack 272 is formed on the substrate 210. The stack 272 has a plurality of sub-array regions (R shown in FIG. 1) and a plurality of openings O penetrating through the stack 272 between the sub-array regions. The stack 272 comprises a plurality of gate electrodes 270 and a plurality of dielectric layers 224 disposed alternately. The active structures 230 penetrate through the stack 272 in the sub-array regions.

As shown in FIG. 2J, a plurality of isolation layers 262 are formed in the openings O along sidewalls of the stack 272. A low temperature oxide deposition process and an etching process may be used, but the disclosure is not limited thereto.

Then, a plurality of connecting structures can be formed in remaining spaces of the openings O. First, first portions of polysilicon are formed along the isolation layers 262. As shown in FIG. 2K, after forming the isolation layers 262, amorphous silicon liners 280 are conformally formed into the openings O. Then, as shown in FIG. 2L, the amorphous silicon liners 280 are annealed to form the first portions 282 of polysilicon.

As shown in FIG. 2M, after forming the first portions 282 of polysilicon, an amorphous silicon material 283 is filled into the openings O. Then, as shown in FIG. 2N, portions of the amorphous silicon material 283 are removed until seams S in the amorphous silicon material 283 are exposed, such as by an etching back process. The remaining portions of amorphous silicon material 283 become second portions 284 of the connecting structures. As such, second portions 284 of amorphous silicon are formed in spaces defined by the first portions 282.

As shown in FIG. 2O, after forming the second portions 284 of amorphous silicon, an amorphous silicon material 285 is filled into remaining spaces of the openings O. Due to the processes, interfaces may be observed between the amorphous silicon material 285 and the second portions 284. The interfaces are defined by the seams S, and thus may have concave shapes. The amorphous silicon material 285 for forming third portions 286 fills the seams originally existing in the amorphous silicon material 283 for forming the second portions 284. As such, there is no seam will be exposed in following processes, and a material used in following processes, such as tungsten for plugs, will not be filled into exposed seams and produce additional undesirable stress to the structure as in conventional semiconductor processes. As shown in FIG. 2P, redundant portions of the amorphous silicon material 285 are removed, such as by an etching back process, and flat surfaces are provided. As such, the third portions 286 of amorphous silicon are formed on the second portions 284. The first portion 282, the second portion 284 and the third portions 286 constitute the connecting structure 288.

As shown in FIG. 2Q, a plurality of plugs 290 are formed on the connecting structures 288. The plugs 290 may be formed of tungsten, but the disclosure is not limited thereto. In addition, a plurality of barrier layers 292 may be formed wrapping the plugs 290, respectively.

While not shown in the drawings, it can be appreciated that other processes may be conducted thereafter. For example, a plurality of vias (170 shown in FIG. 1) may be formed on the active structures 230. The related illustration is omitted herein for simplicity.

The disclosure provides a new structure for the vertical connecting structures (140, 288). The structure has only a thin liner portion (i.e., the first portion) is formed of polysilicon, and the remaining thicker portion (i.e., the combined structure of the second portion and the third portion) is formed of amorphous silicon. In semiconductor processes, polysilicon is typically formed by providing amorphous silicon at first and then thermal treating the amorphous silicon to crystalize the amorphous silicon to form the polysilicon. As such, polysilicon results in more thermal stress than amorphous silicon. Since the connecting structures according to the embodiments are mainly formed of amorphous silicon, the thermal stress produced in the formation of the connecting structures according to the embodiments is much less than that produced in formation of a conventional connecting structures, which is completely formed of polysilicon.

In addition, the amorphous silicon portions of the connecting structures are formed by two-stage processes. Seams produced in the first stage process can be filled in the second stage process. As such, tungsten used for the plugs will not downwardly extend into seams, and thus will not produce additional stress to other components in the structure.

For these reasons, bending of the active structures due to the stress from the connecting structures, particularly due to the annealing process and seams, can be prevented. The vias can properly land on the active structures. As such, short and leakage due to the mis landing of the vias on the gate electrodes can be avoided. For example, leakage between the bit lines and the string select line and the like, which may interrupt Iₒₙ, can be avoided.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate;
a stack disposed on the substrate, the stack having a plurality of sub-array regions, the stack comprising a plurality of gate electrodes and a plurality of dielectric layers disposed alternately;
a plurality of active structures penetrating through the stack in the sub-array regions, wherein a plurality of memory cells are defined by cross points of the gate electrodes and the active structures;
a plurality of connecting structures penetrating through the stack between the sub-array regions, each of the connecting structures comprises:
a first portion formed as an outermost layer of the connecting structure, wherein the first portion is formed of polysilicon;
a second portion disposed in a space defined by the first portion, wherein the second portion is formed of amorphous silicon; and
a third portion disposed on the second portion, wherein the third portion is formed of amorphous silicon; and
a plurality of isolation layers disposed between sidewalls of the stack and the connecting structures.

2. The semiconductor structure according to claim 1, wherein a combined structure of the second portion and the third portion are surrounded by the first portion.

3. The semiconductor structure according to claim 1, further comprising:
a plurality of plugs disposed on the connecting structures; and
a plurality of barrier layers wrapping the plugs, respectively.

4. The semiconductor structure according to claim 3, wherein the plugs have substantially flat bottom surfaces.

5. The semiconductor structure according to claim 1, wherein each of the active structures comprises:
a memory layer formed as an outermost layer of the active structure;
a channel layer disposed along the memory layer;
a dielectric material disposed in a space defined by the channel layer; and
a contact disposed on the dielectric material.

6. The semiconductor structure according to claim 5, further comprising:
an electronic device layer disposed on the substrate; and
a bottom conductive layer disposed on the electronic device layer;
wherein the stack is disposed on the bottom conductive layer, the active structures penetrate through the stack and the bottom conductive layer and land on the electronic device layer, and the connecting structures stop in the bottom conductive layer and electrically connect with the bottom conductive layer.

7. The semiconductor structure according to claim 6, wherein the memory layers have disconnections in the bottom conductive layer such that the channel layers are connected by the bottom conductive layer.

8. The semiconductor structure according to claim 6, further comprising:
a plurality of vias landing on the active structures.

9. The semiconductor structure according to claim 8, wherein the bottom conductive layer is functioned as a common source line, the connecting structures are functioned as common source line connecting structures, the gate electrodes in the stack are further functioned as a string select line, word lines and a ground select line, and the semiconductor structure further comprises a plurality of bit lines disposed over the stack and connected to the active structures through the vias.

10. A method for manufacturing a semiconductor structure, comprising:
providing a partially formed structure comprising a substrate, a stack and a plurality of active structures, wherein the stack is formed on the substrate, the stack has a plurality of sub-array regions and a plurality of openings penetrating through the stack between the sub-array regions, the stack comprises a plurality of gate electrodes and a plurality of dielectric layers disposed alternately, and the active structures penetrate through the stack in the sub-array regions;
forming a plurality of isolation layers in the openings along sidewalls of the stack; and
forming a plurality of connecting structures in remaining spaces of the openings, comprising:
forming first portions of polysilicon along the isolation layers;
forming second portions of amorphous silicon in spaces defined by the first portions; and
forming third portions of amorphous silicon on the second portions.

11. The method according to claim 10, wherein providing the partially formed structure comprising:
forming an initial stack on the substrate, the initial stack comprising a plurality of sacrificial layers and a plurality of dielectric layers formed alternately;
forming the active structures penetrating through the initial stack in the sub-array regions, each of the active structures comprising:
a memory layer formed along a sidewall of the initial stack;
a channel layer formed along the memory layer;
a dielectric material formed in a space defined by the channel layer; and
a contact formed on the dielectric material:
forming the openings penetrating through the initial stack between the sub-array regions; and
replacing the sacrificial layers of the initial stack with gate electrodes to form the stack.

12. The method according to claim 11, wherein providing the partially formed structure further comprising:
before forming the initial stack, forming an electronic device layer on the substrate;
forming a bottom stop layer on the electronic device layer;
forming a first bottom dielectric layer on the bottom stop layer;
forming a bottom sacrificial layer on the first bottom dielectric layer;
forming a second bottom dielectric layer on the bottom sacrificial layer; and
forming an etch stop layer on the second bottom dielectric layer,
wherein the initial stack is formed on the etch stop layer, the active structures further penetrate through the etch stop layer, the second bottom dielectric layer, the bottom sacrificial layer, the first bottom dielectric layer and the bottom stop layer and land on the electronic device layer, and the openings further penetrate through the etch stop layer and the second bottom dielectric layer and stop in the bottom sacrificial layer.

13. The method according to claim 11, wherein providing the partially formed structure further comprising:
after forming the openings, removing the bottom sacrificial layer through the openings;
removing portions of the memory layers located at positions corresponding to the bottom sacrificial layer through the openings;
removing the first bottom dielectric layer and the second bottom dielectric layer through the openings; and
filling a conductive material into a space formed by removing the bottom sacrificial layer, the portions of the memory layers, the first bottom dielectric layer and the second bottom dielectric layer.

14. The method according to claim 13, wherein the bottom stop layer and the etch stop layer are conductive, and the conductive material filled into the space formed by removing the bottom sacrificial layer, the portions of the memory layers, the first bottom dielectric layer and the second bottom dielectric layer together with the bottom stop layer and the etch stop layer constitutes a bottom conductive layer.

15. The method according to claim 11, wherein forming the first portions of polysilicon comprising:
after forming the isolation layers, conformally forming amorphous silicon liners into the openings; and
annealing the amorphous silicon liners to form the first portions of polysilicon.

16. The method according to claim 11, wherein forming the second portions of amorphous silicon comprising:
after forming the first portions of polysilicon, filling an amorphous silicon material into the openings; and
removing portions of the amorphous silicon material until seams in the amorphous silicon material are exposed.

17. The method according to claim 16, wherein forming the third portions of amorphous silicon comprising:
after forming the second portions of amorphous silicon, filling an amorphous silicon material into remaining spaces of the openings.

18. The method according to claim 17, wherein the amorphous silicon material for forming the third portions fills the seams originally existing in the amorphous silicon material for forming the second portions.

19. The method according to claim 11, further comprising:
forming a plurality of plugs on the connecting structures; and
forming a plurality of barrier layers wrapping the plugs, respectively.

20. The method according to claim 11, further comprising:
forming a plurality of vias on the active structures.
